(19) United States
(12) Patent Application Publication
(10) Pub. No.: US 2026/0058633 A1
(43) Pub. Date: Feb. 26, 2026

(54) ACOUSTIC WAVE DEVICE FOR ASYMMETRIC FREQUENCY BANDS AND MANUFACTURING METHOD, CHARGE WHEN COMPRESSED, TWISTED, OR DISTORTED, AND SIMILARLY COMPRESS, TWIST, OR DISTORT WHEN A CHARGE IS APPLIED

(71) Applicant: Qorvo US, Inc., Greensboro, NC (US)

(72) Inventors: Jyothi Swaroop Sadhu, Sanford, FL (US); Andreas Tag, Altamonte Springs, FL (US); Seyed Amin Sandoughsaz Zardini, Sanford, FL (US); Alfred Gimenez, Altamonte Springs, FL (US); Kalyan Karnati, Apopka, FL (US)

(21) Appl. No.: 18/996,226

(22) PCT Filed: Aug. 18, 2023
(86) PCT No.: PCT/US2023/030591

§ 371 Date: Jan. 17, 2025

Related U.S. Application Data
(60) Provisional application No. 63/401,433, filed on Aug. 26, 2022.

(51) Int. Cl. H03H 9/15; H03H 3/02; H03H 9/13

(52) U.S. Cl. CPC H03H 9/15; H03H 3/02; H03H 9/13

(57) ABSTRACT

The present disclosure relates to an acoustic wave device for asymmetric frequency bands and a manufacturing process for making the same. The disclosed acoustic wave device includes at least one first electrode (102:152), at least one second electrode (104:152), a first piezoelectric layer (114) with a recess (116), and a second piezoelectric layer (118) fully covering the recess. Herein, the at least one first electrode is formed over the first piezoelectric layer, and the at least one second electrode is formed over the second piezoelectric layer and confined within the recess. The second piezoelectric layer does not cover a portion of the first piezoelectric layer, which is vertically underneath the at least one first electrode. The first piezoelectric layer and the second piezoelectric layer are formed of different piezoelectric materials.

### RELATED APPLICATIONS

This application claims the benefit of provisional patent application Ser. No. 63/401,433, filed Aug. 26, 2022, the disclosure of which is hereby incorporated herein by reference in its entirety.

### FIELD OF THE DISCLOSURE

The present disclosure relates to an acoustic wave device for asymmetric frequency bands and a manufacturing process for making the same.

### BACKGROUND

Acoustic wave devices are widely used in modern electronics. At a high level, acoustic wave devices include a piezoelectric layer in contact with one or more electrodes. Materials suitable for use in the piezoelectric layer acquire a charge when compressed, twisted, or distorted, and similarly compress, twist, or distort when a charge is applied to them. Accordingly, when an alternating electrical signal is applied to the one or more electrodes in contact with the piezoelectric layer, a corresponding mechanical signal (i.e., an oscillation or vibration) is transduced therein. Based on the characteristics of the one or more electrodes on the piezoelectric layer, the properties of the material used in the piezoelectric layer, and other factors such as the shape of the acoustic wave device and other structures provided on the device, the mechanical signal transduced in the piezoelectric layer exhibits a frequency dependence on the alternating electrical signal. Acoustic wave devices leverage this frequency dependence to provide one or more functions.

Exemplary acoustic wave devices include surface acoustic wave (SAW) resonators and bulk acoustic wave (BAW) resonators, which are increasingly used to form filters used in the transmission and reception of radio frequency (RF) signals for communication. Due to the stringent demands placed on filters for modern RF communications systems, acoustic wave devices for these applications are desired to provide a high quality factor and wide bandwidth (i.e., high electromechanical coupling coefficient), and be small in size.

In conventional acoustic wave device designs, each device die only includes one piezoelectric layer formed of a single piezoelectric material. One piezoelectric material can only have a relatively high electromechanical coupling coefficient with a relatively low quality factor, or a relatively high quality factor with a relatively low electromechanical coupling coefficient. The conventional device die compromises between the electromechanical coupling coefficient and the quality factor. Consequently, filters formed of these conventional device dies will result in a relatively wide bandwidth (i.e., the relatively high electromechanical coupling coefficient) with degraded skirt steepness (i.e., the relatively low quality factor) or a relatively steep skirt (i.e., the high quality factor) with a degraded bandwidth (i.e., the relatively low electromechanical coupling coefficient).

However, in many applications, a frequency band of one filter is asymmetric. For example, B3 transmit band (1710-1785 MHz) requests a high steepness on an upper band edge due to proximity of a receiving path on its right, while a lower band edge can be extended and has no strict rejection spec. In another example, B41F band (2496-2690 MHz) needs a high steepness on a lower band edge due to WiFi channels, while an upper band edge has no strict rejection spec.

In light of the above, there is a present need for improved acoustic wave device designs to achieve desired features of both quality factor and the electromechanical coupling coefficient for asymmetric frequency band applications. Further, there is also a need to keep the final product size competitive.

### SUMMARY

The present disclosure relates to an acoustic wave device for asymmetric frequency bands and a manufacturing process for making the same. The disclosed acoustic wave device includes at least one first electrode, at least one second electrode, a first piezoelectric layer with a first recess, and a second piezoelectric layer fully covering the first recess. Herein, the at least one first electrode is formed over the first piezoelectric layer, and the at least one second electrode is formed over the second piezoelectric layer and confined within the first recess. The second piezoelectric layer does not cover a portion of the first piezoelectric layer that is vertically underneath the at least one first electrode. The first piezoelectric layer and the second piezoelectric layer are formed of different piezoelectric materials.

In one embodiment of the acoustic wave device, the first recess has tapered sidewalls, such that a width of the first recess decreases from an upper portion to a lower portion of the first recess, wherein an angle formed between the tapered side walls and a horizontal plane is between 20 and 55 degrees.

In one embodiment of the acoustic wave device, the first recess does not extend completely through the first piezoelectric layer. The first piezoelectric layer includes a first piezoelectric section directly underneath the first recess, such that the second piezoelectric layer is formed over first piezoelectric section. The first piezoelectric section has a thickness between 0 μm and 0.2 μm.

In one embodiment of the acoustic wave device, the first piezoelectric layer and the second piezoelectric layer have different quality factors and different electromechanical coupling coefficients.

In one embodiment of the acoustic wave device, each of the first piezoelectric layer and the second piezoelectric layer is formed of one of aluminum nitride (AlN), scandium-doped aluminum nitride (ScAlN), magnesium hydrofluoric acid aluminum nitride (MgHfAlN), magnesium zirconium aluminum nitride (MgZrAlN), and magnesium titanium aluminum nitride (MgTiAlN).

In one embodiment of the acoustic wave device, the first piezoelectric layer is formed of AlN, and the second piezoelectric layer is formed of one of ScAlN, MgHfAlN, MgZrAlN, and MgTiAlN.

According to one embodiment, the acoustic wave device further includes a bottom electrode structure with a first bottom electrode and a second bottom electrode. Herein, the at least one first electrode includes a first top electrode, and the at least one second electrode includes a second top electrode. The second piezoelectric layer extends over a top surface of the first piezoelectric layer. The bottom electrode structure is formed underneath the first piezoelectric layer. The first bottom electrode is vertically underneath the first top electrode, and the second bottom electrode is vertically underneath the second top electrode. A first resonator is composed of at least the first bottom electrode, the first top electrode, and a portion of the first piezoelectric layer vertically between the first bottom electrode and the first top electrode. A second resonator is composed of at least the second bottom electrode, the second top electrode, and the second piezoelectric layer.

According to one embodiment, the acoustic wave device further includes a reflection structure with a first reflector and a second reflector. Herein, each of the first reflector and the second reflector has alternating high acoustic impedance sections and low acoustic impedance sections. The first reflector is vertically underneath the first bottom electrode, and the first resonator further includes the first reflector. The second reflector is vertically underneath the second bottom electrode, and the second resonator further includes the second reflector.

In one embodiment of the acoustic wave device, the first piezoelectric layer is formed of lithium tantalate (LT), Lithium niobate, or quartz, and the second piezoelectric layer is formed of one of AlN, ScAlN, MgHfAlN, MgZrAlN, and MgTiAlN.

In one embodiment of the acoustic wave device, the at least one first electrode includes two or more first interdigital transducer (IDT) electrodes, and the at least one second electrode includes two or more second IDT electrodes. Herein, the first IDT electrodes are formed over the first piezoelectric layer, and the second IDT electrodes are formed over the second piezoelectric layer and are confined within the second piezoelectric layer. A first resonator is composed of at least the first IDT electrodes and a portion of the first piezoelectric layer vertically underneath the first IDT electrodes, and a second resonator is composed of at least the second IDT electrodes and the second piezoelectric layer underneath the second IDT electrodes. A top surface of the first piezoelectric layer and a top surface of the second piezoelectric layer are coplanar.

In one embodiment of the acoustic wave device, the at least one first electrode includes multiple first top electrodes, the at least one second electrode includes multiple second top electrodes, and the first piezoelectric layer further includes a second recess. Herein, the second piezoelectric layer continuously covers both the first recess and the second recess and does not cover any portion of the first piezoelectric layer, which is vertically underneath each of the multiple first top electrodes. The multiple first top electrodes are formed over the first piezoelectric layer, and the multiple second top electrodes are formed over the second piezoelectric layer. Two of the multiple second top electrodes are confined within the first recess and the second recess, respectively.

According to one embodiment, a method for manufacturing an acoustic wave device starts with providing an acoustic wave device precursor with an intact first piezoelectric layer. A first piezoelectric layer with a recess, which extends from a top surface of the intact first piezoelectric layer towards a bottom surface of the intact first piezoelectric layer, is then formed by removing a portion of the intact first piezoelectric layer. Next, a common second piezoelectric layer that covers the entire first piezoelectric layer is deposited, such that the common second piezoelectric layer is in contact with an entire top surface of the first piezoelectric layer and exposed surfaces within the recess. After the deposition of the common second piezoelectric layer, the common second piezoelectric layer is patterned to provide a second piezoelectric layer. Herein, the second piezoelectric layer fully covers the recess and does not cover the entire first piezoelectric layer. The second piezoelectric layer is formed of a different piezoelectric material from the first piezoelectric layer. Then, at least one first electrode is formed over the first piezoelectric layer, and at least one second electrode is formed over the second piezoelectric layer and confined within the recess. The at least one first electrode does not have overlap with the second piezoelectric layer.

In one embodiment of the method for manufacturing the acoustic wave device, forming the recess includes forming a starting recess from the top surface of the intact first piezoelectric layer towards the bottom surface of the intact first piezoelectric layer without completely extending through the intact first piezoelectric layer. Herein, a piezoelectric section of the intact first piezoelectric layer remains directly underneath the starting recess. Next, the remaining piezoelectric section is thinned down to provide the recess with a thinned piezoelectric section directly underneath the recess.

In one embodiment of the method for manufacturing the acoustic wave device, the starting recess is formed by one of a piezoelectric milling process, a dry-etching process, and a wet-etching process. The remaining piezoelectric section is thinned down by a trimming process. A top surface of the thinned piezoelectric section has a roughness less than 1 nm, and the thinned piezoelectric section has a thickness between 0 and 0.2 μm.

In one embodiment of the method for manufacturing the acoustic wave device, the recess has tapered sidewalls, such that a width of the recess decreases from an upper portion to a lower portion of the recess. An angle formed between the tapered side walls and a horizontal plane is between 20 and 55 degrees.

In one embodiment of the method for manufacturing the acoustic wave device, the common second piezoelectric layer is patterned by one of a piezoelectric milling process, a dry-etching process, and a wet-etching process.

In one embodiment of the method for manufacturing the acoustic wave device, the first piezoelectric layer and the second piezoelectric layer have different quality factors and different electromechanical coupling coefficients.

In one embodiment of the method for manufacturing the acoustic wave device, each of the first piezoelectric layer and the second piezoelectric layer is formed of one of AlN, ScAlN, MgHfAlN, MgZrAlN, and MgTiAlN.

In one embodiment of the method for manufacturing the acoustic wave device, the first piezoelectric layer is formed of AlN, and the second piezoelectric layer is formed of one of a group consisting of ScAlN, MgHfAlN, MgZrAlN, and MgTiAlN.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an exemplary acoustic wave device according to some embodiments of the present disclosure.

FIGS. 2A-2B illustrate an alternative acoustic wave device according to some embodiments of the present disclosure.

FIG. 3 illustrates insertion loss comparison between the alternative acoustic wave device and conventional acoustic wave devices.

FIG. 4 illustrates another alternative acoustic wave device according to some embodiments of the present disclosure.

FIGS. 5A-11 illustrate an exemplary manufacturing process to implement the acoustic wave device shown in FIG. 1.

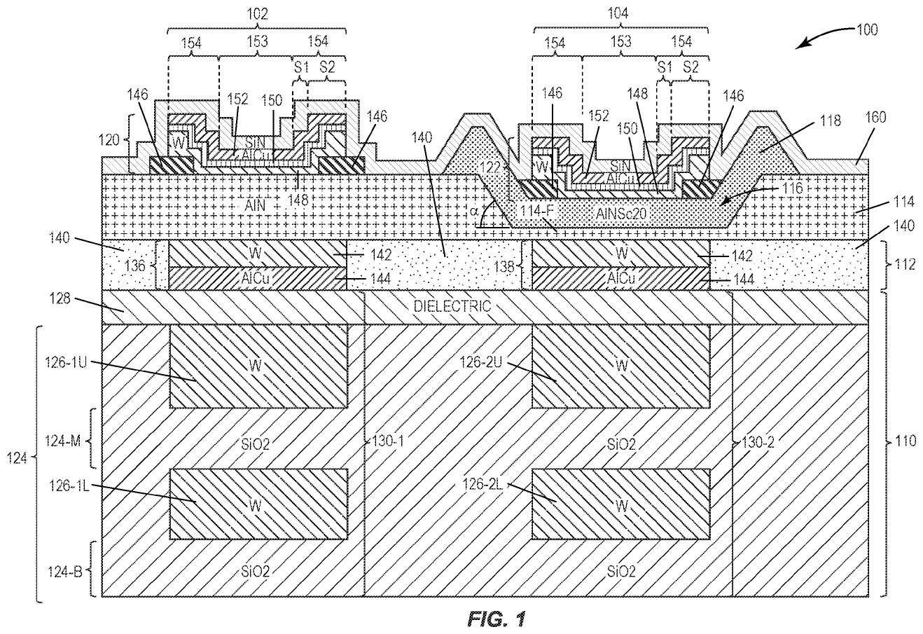

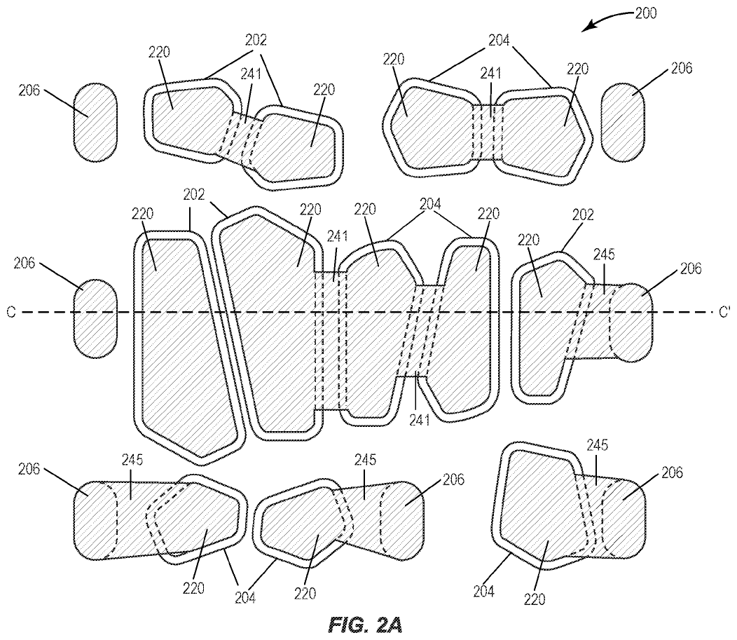

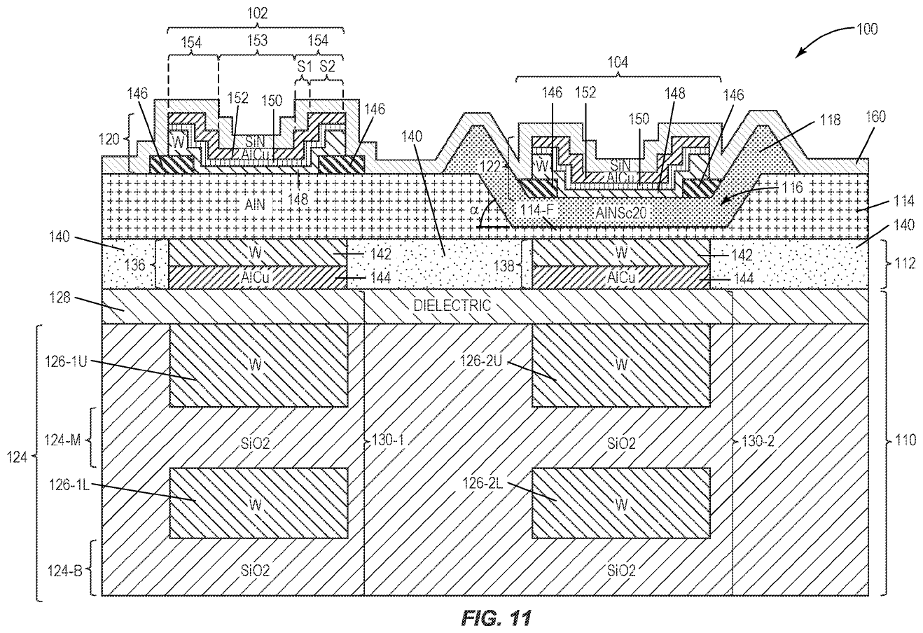

It will be understood that for clear illustrations, FIGS. 1-11 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

FIG. 1 illustrates an exemplary acoustic wave device 100 according to some embodiments of the present disclosure. For the purpose of this illustration, the acoustic wave device 100 includes a first resonator 102 and a second resonator 104, each of which is a Bulk Acoustic Wave (BAW) solidly mounted resonator (SMR). In different applications, the acoustic wave device 100 may include more resonators, and each resonator may be another type of resonator, such as a film bulk acoustic resonator (FBAR), a common surface acoustic wave (SAW) resonator, a temperature compensated (TC) SAW resonator, a Guided SAW resonator, a mixture of SAW/BAW resonators (e.g., XBAW resonator), and the like. Note that the first resonator 102 and the second resonator 104 have different piezoelectric materials.

In detail, the acoustic wave device 100 includes a reflection structure 110, a bottom electrode structure 112 over the reflection structure 110, a first piezoelectric layer 114 with a recess 116 over the bottom electrode structure 112, a second piezoelectric layer 118 fully covering the recess 116 and extending over a top surface of the first piezoelectric layer 114, a first top electrode 120, and a second top electrode 122. The first piezoelectric layer 114 and the second piezoelectric layer 118 are formed of different piezoelectric materials.

In one embodiment, the reflection structure 110 includes a low acoustic impedance region 124, multiple high acoustic impedance sections 126 are embedded within the low acoustic impedance region 124, and a dielectric layer 128. For the purpose of this illustration, there are four high acoustic impedance sections 126: a first upper high acoustic impedance section 126-1U, a first lower high acoustic impedance section 126-1L, a second upper high acoustic impedance section 126-2U, and a second lower high acoustic impedance section 126-2L. In different applications, there may be fewer or more high acoustic impedance sections 126 embedded in the low acoustic impedance region 124.

Herein, the first lower high acoustic impedance section 126-1L and the second lower high acoustic impedance section 126-2L reside over a bottom portion 124-B of the low acoustic impedance region 124. The first upper high acoustic impedance section 126-1U is vertically above the first lower high acoustic impedance section 126-1L and is separate from the first lower high acoustic impedance section 126-1L by a middle portion 124-M of the low acoustic impedance region 124. Similarly, the second upper high acoustic impedance section 126-2U is vertically above the second lower high acoustic impedance section 126-2L and is also separate from the second lower high acoustic impedance section 126-2L by the middle portion 124-M of the low acoustic impedance region 124. In one embodiment, a top surface of the first upper high acoustic impedance section 126-1U, a top surface of the second upper high acoustic impedance section 126-2U, and a top surface of the low acoustic impedance region 124 are coplanar.

The dielectric layer 128 is formed over the low acoustic impedance region 124 and the high acoustic impedance sections 126 embedded within the low acoustic impedance region 124. In one embodiment, the dielectric layer 128 is in contact with the top surface of the first upper high acoustic impedance section 126-1U, the top surface of the second upper high acoustic impedance section 126-2U, and the top surface of the low acoustic impedance region 124.

The first upper high acoustic impedance section 126-1U, the first lower high acoustic impedance section 126-1L, a section of the bottom portion 124-B of the low acoustic impedance region 124 directly underneath the first lower high acoustic impedance section 126-1L, a section of the middle portion 124-M of the low acoustic impedance region 124 vertically between the first upper and lower high acoustic impedance sections 126-1U and 126-1L, and a section of the dielectric layer 128 directly over the first upper high acoustic impedance section 126-1U constitute a first reflector 130-1. The second upper high acoustic impedance section 126-2U, the second lower high acoustic impedance section 126-2L, another section of the bottom portion 124-B of the low acoustic impedance region 124 directly underneath the second lower high acoustic impedance section 126-2L, another section of the middle portion 124-M of the low acoustic impedance region 124 vertically between the second upper and lower high acoustic impedance sections 126-2U and 126-2L, and another section of the dielectric layer 128 directly over the second upper high acoustic impedance section 126-2U constitute a second reflector 130-2. The low acoustic impedance region 124 has a lower acoustic impedance, a lower density, and a lower stiffness than the high acoustic impedance sections 126, and may be formed of silicon oxide (SiO₂) or aluminum (Al). Each high acoustic impedance section 126 is formed of a high acoustic impedance material, such as tungsten (W), molybdenum (Mo), or platinum (Pt). The dielectric layer 128 may be formed of SiO₂. In some applications, such as FBAR applications, the reflection structure 110 is omitted in the acoustic wave device 100.

The bottom electrode structure 112 is formed over the dielectric layer 128 of the reflection structure 110 and includes a first bottom electrode 136, a second bottom electrode 138, and planarization oxide 140. The first bottom electrode 136 is vertically above the first reflector 130-1, and the second bottom electrode 138 is vertically above the second reflector 130-2. The planarization oxide 140 surrounds the first bottom electrode 136 and the second bottom electrode 138 and is capable of electrically separating the first bottom electrode 136 and the second bottom electrode 138. Each bottom electrode 136/138 may include two bottom electrode layers 142 and 144. The second bottom electrode layer 144 is over the dielectric layer 128 and may be formed of aluminum copper (AlCu), while the first bottom electrode layer 142 is over the second bottom electrode layer 144 and may be formed of W, Mo, or Pt.

The first piezoelectric layer 114 with the recess 116 is formed over the bottom electrode structure 112. The recess 116 has tapered sidewalls such that a width of the recess 116 decreases from an upper portion to a lower portion of the recess 116. An angle a formed between the tapered side walls and a horizontal plane (e.g., parallel with a bottom surface of the first piezoelectric layer 114) is between 20 and 55 degrees. In one embodiment, the recess 116 extends from the top surface of the first piezoelectric layer 114 towards the bottom surface of the first piezoelectric layer 114 without completely extending through the first piezoelectric layer 114. A thin piezoelectric section 114-F of the first piezoelectric layer 114 is directly underneath the recess 116. In one embodiment, the recess 116 may extend completely through the first piezoelectric layer 114 from the top surface of the first piezoelectric layer 114 to the bottom surface of the first piezoelectric layer 114 (not shown). The recess 116 is vertically above the second bottom electrode 138.

The second piezoelectric layer 118 fully covers the recess 116 (i.e., covers a bottom surface and the sidewalls of the recess 116) and extends over the top surface of the first piezoelectric layer 114, such that the second piezoelectric layer 118 is also vertically above the second bottom electrode 138. The second piezoelectric layer 118 does not cover a portion of the first piezoelectric layer 114, which is vertically above the first bottom electrode 136. The first piezoelectric layer 114 and the second piezoelectric layer 118 are formed of two different piezoelectric materials, each of which is one of aluminum nitride (AlN), scandium-doped aluminum nitride (ScAlN), magnesium hydrofluoric acid aluminum nitride (MgHAlN), magnesium zirconium aluminum nitride (MgZrAlN), and magnesium titanium aluminum nitride (MgTiAlN). In a non-limited example, the first piezoelectric layer 114 may be formed of AlN, which has a relatively high quality factor, while the second piezoelectric layer 118 may be formed of ScAlN, an electromechanical coupling coefficient (k2e) of which depends on a percentage of Sc (i.e., the higher the percentage of Sc, the higher the electromechanical coupling coefficient of the ScAlN). Instead of ScAlN, the second piezoelectric layer 118 may be formed of MgHfAlN, MgZrAlN, or MgTiAlN. The first piezoelectric layer 114 has a thickness between 0.3 μm and 1.4 μm, and the second piezoelectric layer 118 has a thickness between 0.2 μm and 1 μm. When the recess 116 does not extend completely through the first piezoelectric layer 114, the thin piezoelectric section 114-F has a thin thickness between 0 μm and 0.2 μm, or between 20 nm and 40 nm. The thin piezoelectric section 114-F is vertically between the second piezoelectric layer 118 and the second bottom electrode 138. When the recess 116 extends completely through the first piezoelectric layer 114, the thin piezoelectric section 114-F is omitted, and the second piezoelectric layer 118 is in contact with the second bottom electrode 138 (not shown).

The first top electrode 120 is formed over the first piezoelectric layer 114 and is vertically above the first bottom electrode 136. The second top electrode 122 is formed over the second piezoelectric layer 118, is confined within the recess 116, and is vertically above the second bottom electrode 138. Each top electrode 120/122 may include a spacer ring 146 formed around a periphery of the top electrodes 120/122, a first top electrode layer 148 formed over the first/second piezoelectric layers 114/118 and extending over the spacer ring 146, an electrode seed layer 150 formed over the first top electrode layer 148, and a second top electrode layer 152 formed over the electrode seed layer 150. Typically, the top electrodes 120/122 can be divided into a central region 153 and a border (BO) region 154, which surrounds the central region 153 and is at the periphery of the top electrodes 120/122. In one embodiment, the BO region 154 may have a dual-step configuration with an inner step S1 and an outer step S2. U.S. Patent Application Publication No. 20200228089 describes an apparatus and method for formation of components such as the top electrodes 120/122 with dual-step configuration.

Herein, the spacer ring 146 may be formed of a dielectric material, such as silicon dioxide, silicon nitride, aluminum nitride, or combinations thereof. The first top electrode layer 148 may be formed of W, Mo, Pt, or other electrically conductive materials with high acoustic impedance properties. The electrode seed layer 150 may be formed of Titanium Tungsten (TiW) or Titanium (Ti). The second top electrode layer 152 may be formed of AlCu or other highly electrically conductive materials.

Herein, the first resonator 102 (e.g., a BAW SMR) is composed of the first reflector 130-1, the first bottom electrode 136, the first top electrode 120, and a portion of the first piezoelectric layer 114 vertically between the first bottom electrode 136 and the first top electrode 120. The second resonator 104 (e.g., a BAW SMR) is composed of the second reflector 130-2, the second bottom electrode 138, the second top electrode 122, and the second piezoelectric layer 118. When the recess 116 does not extend completely through the first piezoelectric layer 114, the second resonator 104 further includes the thin piezoelectric section 114-F. Due to the relatively thin thickness of the thin piezoelectric section 114-F (compared to the thickness of the second piezoelectric layer 118), the second resonator 104 is essentially based on the quality factor and the electromechanical coupling coefficient of the second piezoelectric layer 118. In different applications, like the FBAR applications, the first resonator 102 does not include the first reflector 130-1 and is composed of the first bottom electrode 136, the first top electrode 120, and a portion of the first piezoelectric layer 114 vertically between the first bottom electrode 136 and the first top electrode 120. The second resonator 104 does not include the second reflector 130-2 and is composed of the second bottom electrode 138, the second top electrode 122, and the second piezoelectric layer 118.

Notice that the acoustic wave device 100 with the first resonator 102 and the second resonator 104 is formed on one acoustic wave wafer by a same manufacturing process (details described below). Compared to a conventional acoustic wave device (formed on one acoustic wave wafer) including only one piezoelectric material, the acoustic wave device 100 includes at least two piezoelectric materials and can achieve desired frequency band characteristics, such as a desired bandwidth at one band edge and desired skirt steepness at another band edge.

Furthermore, the acoustic wave device 100 may also include a passivation layer 160 to protect the acoustic wave device 100 from an external environment. The passivation layer 160 covers the first top electrode 120, the second top electrode 122, portions of the first piezoelectric layer 114 exposed through the first top electrode 120 and the second piezoelectric layer 118, and portions of the second piezoelectric layer 118 exposed through the second top electrode 122. The passivation layer 160 may be formed of Silicon Nitride (SiN), SiO₂, or Silicon Oxynitride (SiON), with a thickness between 250 Å and 5000 Å.

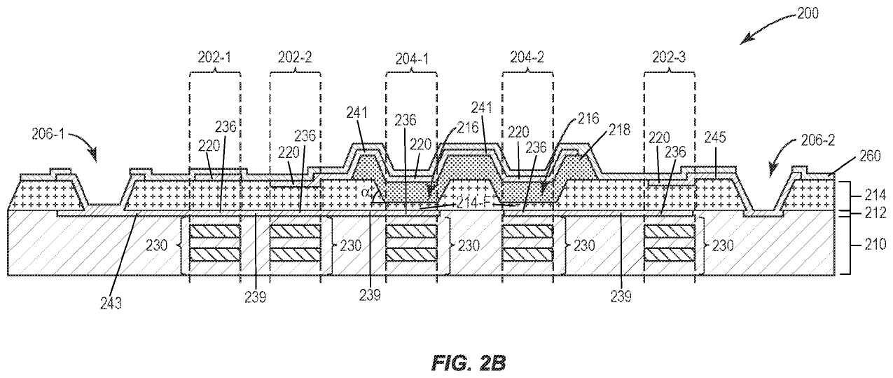

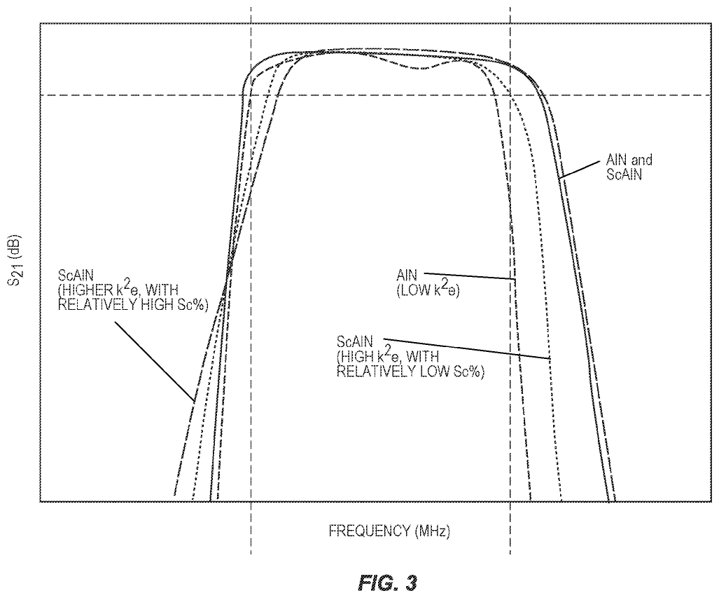

In FIG. 1, the acoustic wave device 100 is illustrated to include two resonators with two different piezoelectric materials. In different applications, one acoustic wave device may include more resonators with different piezoelectric materials. FIGS. 2A-2B illustrate an alternative acoustic wave device 200, which includes multiple resonators according to some embodiments of the present disclosure. FIG. 2A shows a top view of the alternative acoustic wave device 200, and FIG. 2B shows a cross-section view of the alternative acoustic wave device 200 along a dashed line C-C′. For the purpose of this illustration, the alternative acoustic wave device 200 includes five type-A resonators 202, seven type-B resonators 204, and seven device vias 206. Each type-A resonator 202 has a similar configuration as the first resonator 102 shown in FIG. 1, and each type-B resonator 204 has a similar configuration as the second resonator 104 shown in FIG. 1. In different applications, the alternative acoustic wave device 200 may include fewer or more type-A resonators 202, and fewer or more type-B resonators 204. In addition, each resonator 202/204 in the alternative acoustic wave device 200 may be an FBAR, a common SAW resonator, a TC SAW resonator, a Guided SAW resonator, a mixture of SAW/BAW resonator (e.g., XBAW resonator), and the like.

As illustrated in FIG. 2B, the alternative acoustic wave device 200 includes a reflection structure 210, a bottom electrode structure 212 over the reflection structure 210, a first piezoelectric layer 214 with multiple recesses 216 over the bottom electrode structure 212, a second piezoelectric layer 218 fully covering each recess 216 and extending over a top surface of the first piezoelectric layer 214, and multiple top electrodes 220. The first piezoelectric layer 214 and the second piezoelectric layer 218 are formed of different piezoelectric materials.

The reflection structure 210 includes multiple reflectors 230, each of which belongs to a corresponding resonator 202/204. Each reflector 230 may have a same configuration as the first or second reflector 130-1 or 130-2 as shown in FIG. 1. In some applications, such as FBAR applications, the reflection structure 210 is omitted in the alternative acoustic wave device 200. As such, each resonator 202/204 does not include the reflector 230.

The bottom electrode structure 212 resides over the reflection structure 210 and includes multiple bottom electrodes 236, each of which belongs to a corresponding resonator 202/204. Each bottom electrode 236 has a same configuration as the first or second bottom electrode 136 or 138 as shown in FIG. 1. In one embodiment, the bottom electrode structure 212 further includes bottom electrode connections 239 for connecting the bottom electrodes 236 of different resonators 202/204 (e.g., the bottom electrode 236 of a first type-A resonator 202-1, the bottom electrode 236 of a second type-A resonator 202-2, and the bottom electrode 236 of a first type-B resonator 204-1 are connected together by some of the bottom electrode connections 239, and the bottom electrode 236 of a third type-A resonator 202-3 and the bottom electrode 236 of a second type-B resonator 204-2 are connected together by one of the bottom electrode connections 239). Each bottom electrode 236 and each bottom electrode connection 239 are formed from the same electrode layers.

The first piezoelectric layer 214 formed over the bottom electrode structure 212 includes multiple recesses 216. Each recess 216 has tapered sidewalls such that a width of one recess 216 decreases from an upper portion to a lower portion of the recess 216. An angle a formed between the tapered side walls and a horizontal plane (e.g., parallel with a bottom surface of the first piezoelectric layer 214) is between 20 and 55 degrees. In one embodiment, each recess 216 extends from the top surface of the first piezoelectric layer 214 towards the bottom surface of the first piezoelectric layer 214 without completely extending through the first piezoelectric layer 214. One thin piezoelectric section 214-F of the first piezoelectric layer 214 is directly underneath a corresponding recess 216. In one embodiment, each recess 216 may extend completely through the first piezoelectric layer 214 from the top surface of the first piezoelectric layer 214 to the bottom surface of the first piezoelectric layer 214 (not shown). Each recess 216 is vertically above a corresponding reflector 230.

The second piezoelectric layer 218 fully covers each recess 216 (e.g., a bottom surface and the sidewalls of each recess 216) and extends over the top surface of the first piezoelectric layer 214. In one embodiment, the second piezoelectric layer 218 may continuously extend across adjacent recesses 216 (e.g., the first type-B resonators 204-1 and the second type-B resonators 204-2 are adjacent to each other). Herein, each of the first and second type-B resonators 204-1 and 204-2 includes a portion of the second piezoelectric layer 218, which is vertically above the corresponding reflector 230. In one embodiment, the second piezoelectric layer 218 may include multiple separate portions to cover different recesses 216 (not shown, e.g., some type-B resonators 204 are not adjacent to each other). Regardless of the continuity of the second piezoelectric layer 218, the second piezoelectric layer 218 does not cover portions of the first piezoelectric layer 214, which are vertically above the reflectors 230 of the first type-A resonators 202.

The first piezoelectric layer 214 and the second piezoelectric layer 218 are formed of different piezoelectric materials. In one embodiment, the first piezoelectric layer 214 may be formed of AlN, while the second piezoelectric layer 218 may be formed of ScAlN (the percentage of Sc may be varied for different applications), MgHfAlN, MgZrAlN, or MgTiAlN. The first piezoelectric layer 214 has a thickness between 0.3 uμand 1.4 μm, and the second piezoelectric layer 218 has a thickness between 0.2 μm and 1 μm. When each recess 216 does not extend completely through the first piezoelectric layer 214, each thin piezoelectric section 214-F has a thickness between 0 μm and 0.2 μm, or between 20 nm and 40 nm, and is vertically between the second piezoelectric layer 218 and the corresponding bottom electrode 236. When each recess 116 extends completely through the first piezoelectric layer 214, the thin piezoelectric sections 214-F are omitted, and the second piezoelectric layer 218 is contact with the corresponding bottom electrodes 236 (not shown).

Each top electrode 220 belongs to a corresponding resonator 202/204 and has a same configuration as the first or second top electrode 120 or 122. In one embodiment, the alternative acoustic wave device 200 further includes top electrode connections 241 for connecting the top electrodes 220 of different resonators 202/204 (e.g., the top electrode 220 of the second type-A resonator 202-2, the top electrode 220 of the first type-B resonator 204-1, and the top electrode 220 of the second type-B resonator 204-2 are connected together by the top electrode connections 241). Each top electrode 220 and each top electrode connection 241 are formed from the same electrode layers.

In addition, the device vias 206 of the alternative acoustic wave device 200 are formed within the first piezoelectric layer 214. Each device via 206 is electrically connected to an adjacent resonator with a bottom electrode lead 243 or a top electrode lead 245. In FIG. 2B, the bottom electrode 236 of the first type-A resonator 202-1 is connected to a first device via 206-1 by one bottom electrode lead 243, and the top electrode 220 of the third type-A resonator 202-3 is connected to a second device via 206-2 by one top electrode lead 245. Herein, the bottom electrode lead 243 is formed from the same electrode layers as the bottom electrode 236, and the top electrode lead 245 is formed from the same electrode layers as the top electrode 220.

Furthermore, the alternative acoustic wave device 200 may also include a passivation layer 260, which is formed over each top electrode 220, portions of the first piezoelectric layer 214 (exposed through the top electrodes 220, the top electrode connection 241, the top electrode lead 245, and the second piezoelectric layer 218), and portions of the second piezoelectric layer 118 (exposed through the top electrodes 220, the top electrode connection 241, and the top electrode lead 245) without covering each device via 206. The passivation layer 260 may be formed of SiN, SiO₂, or SiON, with a thickness between 250 Å and 5000 Å.

Notice that the alternative acoustic wave device 200 including multiple type-A and type-B resonators 202 and 204 is formed on a same wafer and is capable of achieving a filter function. The type-A and type-B resonators 202 and 204 are manufactured within a same process. Compared to a conventional acoustic wave device (formed on a same wafer) including only one piezoelectric material, the alternative acoustic wave device 200 includes at least two piezoelectric materials and can achieve desired frequency band characteristics, such as a desired bandwidth at one band edge and desired skirt steepness at another band edge.

FIG. 3 illustrates an insertion loss (S₂₁) comparison between the alternative acoustic wave device 200 and some conventional acoustic wave devices with one piezoelectric material. In FIG. 3, three dashed curves represent three conventional acoustic wave devices, each of which include one piezoelectric material (e.g., one for AlN, one for ScAlN with a relatively low Sc percentage, and one for ScAlN with a relatively high Sc percentage), and one solid curve represents the alternative acoustic wave device 200 with two piezoelectric materials (e.g., AlN and ScAlN with a relatively high Sc percentage). A first conventional acoustic wave device with piezoelectric material AlN has the steepest band skirt with the narrowest bandwidth at both band edges, a second conventional acoustic wave device with low-Sc piezoelectric material ScAlN has a moderately steep band skirt with a moderate bandwidth at both band edges, and a third conventional acoustic wave device with high Sc piezoelectric material ScAlN has the least steep band skirt with the widest bandwidth at both band edges. The alternative acoustic wave device 200, on the other hand, is capable of achieving the steepest band skirt on a lower band edge (as the first conventional acoustic wave device using piezoelectric material AlN), and of achieving the widest bandwidth on an upper band edge (as the third conventional acoustic wave device using high-Sc piezoelectric material ScAlN). As such, one acoustic wave device including two piezoelectric materials (e.g., the alternative acoustic wave device 200) can meet desired features of both the quality factor (i.e., band skirt steepness) and the electromechanical coupling coefficient (i.e., bandwidth) for asymmetric frequency band applications. In other words, one acoustic wave device including two piezoelectric materials can achieve a desired band skirt steepness on one band edge while achieving a desired bandwidth on another band edge.

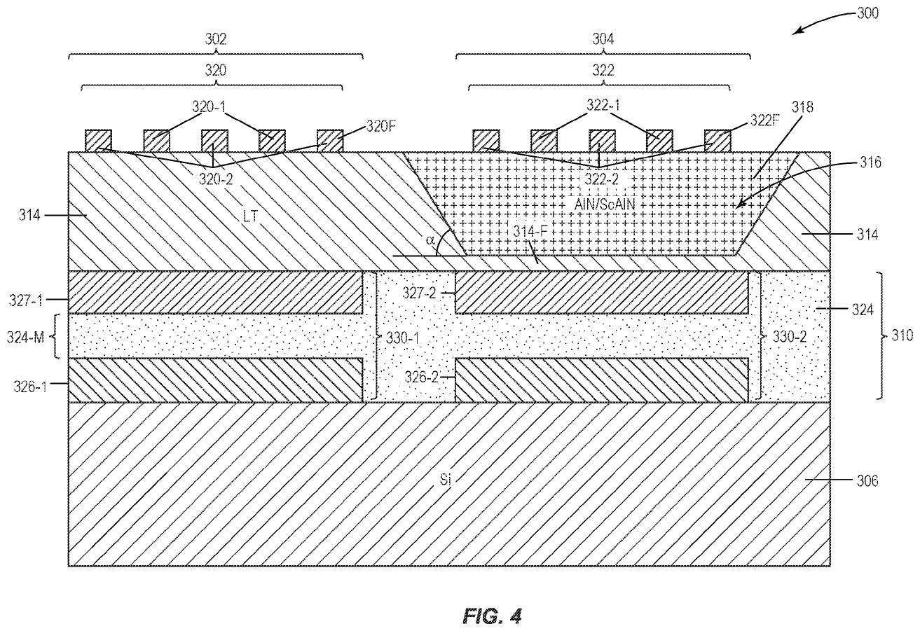

One acoustic wave device with two piezoelectric materials may include two or more BAW resonators as shown in FIGS. 1, 2A and 2B. In different applications, one acoustic wave device with two piezoelectric materials may include two or more SAW resonators. FIG. 4 illustrates another alternative acoustic wave device 300 with SAW resonators. For the purpose of this illustration, the alternative acoustic wave device 300 includes two SAW resonators 302 and 304, each of which is a Guided SAW resonator. In different applications, the acoustic wave device 100 includes more SAW resonators, and each resonator may be a common SAW resonator or a TC SAW resonator.

In detail, the alternative acoustic wave device 300 includes a substrate 306, a reflection structure 310 over the substrate 306, a first piezoelectric layer 314 with a recess 316 over the reflection structure 310, a second piezoelectric layer 318 fully filling the recess 316, two or more first interdigital transducer (IDT) electrodes 320 with multiple first electrode fingers 320-F (e.g., one first IDT electrode 320-1 with two first electrode fingers as an input electrode and another first IDT electrode 320-2 with three first electrode fingers as an output electrode), and two or more second IDT electrodes 322 with multiple second electrode fingers 322-F (e.g., one second IDT electrode 322-1 with two second electrode fingers as an input electrode and another second IDT electrode 322-2 with three second electrode fingers as an output electrode). The first piezoelectric layer 314 and the second piezoelectric layer 318 are formed of different piezoelectric materials.

The substrate 306 may have a thickness between 50 μm and 750 μm and may be formed of various materials including glass, sapphire, quartz, silicon (Si), or gallium arsenide (GaAs) among others, with Si being a common choice. The reflection structure 310 includes a low acoustic impedance region 324, multiple high acoustic impedance sections 326, and multiple functional sections 327. The high acoustic impedance sections 326 and the functional section 327 are embedded within the low acoustic impedance region 324. For the purpose of this illustration, there are two high acoustic impedance sections 326 (e.g., a first high acoustic impedance section 326-1, and a second high acoustic impedance section 326-2) and two functional sections 327 (e.g., a first functional section 327-1, and a second functional section 327-2). In different applications, there may be more high acoustic impedance sections 326 and/or more functional sections 327 embedded in the low acoustic impedance region 324. Herein, the first high acoustic impedance section 326-1 and the second high acoustic impedance section 326-2 are embedded at a bottom portion of the low acoustic impedance region 324 and are in contact with the substrate 306. The first functional section 327-1 is vertically above the first high acoustic impedance section 326-1 and is separated from the first high acoustic impedance section 326-1 by a middle portion 324-M of the low acoustic impedance region 324.

Similarly, the second functional section 327-2 is vertically above the second high acoustic impedance section 326-2 and is also separated from the second high acoustic impedance section 326-2 by the middle portion 324-M of the low acoustic impedance region 324. In one embodiment, a top surface of the first functional section 327-1, a top surface of the second functional section 327-2, and a top surface of the low acoustic impedance region 324 are coplanar.

The first high acoustic impedance section 326-1, the first functional section 327-1, a section of the middle portion 324-M of the low acoustic impedance region 324 vertically located between the first high acoustic impedance section 326-1 and the first functional section 327-1 constitute a first reflector 330-1. The second high acoustic impedance section 326-2, the second functional section 327-2, and another section of the middle portion 324-M of the low acoustic impedance region 324 vertically located between the second high acoustic impedance sections 326-2 and the second functional section 327-2 constitute a second reflector 330-2. The low acoustic impedance region 324 has lower acoustic impedance, lower density, and lower stiffness than the high acoustic impedance sections 326, and may be formed of SiO₂ or Al. The high acoustic impedance sections 326 are formed of a high acoustic impedance material, such as W, Mo, or Pt. In addition, the functional sections 327 may be formed of one or more dielectric materials, such as oxide and nitride, or one or more metal materials, such as Pt, W, and ruthenium (Ru).

The first piezoelectric layer 314 with the recess 316 is formed over the reflection structure 310. The recess 316 has tapered sidewalls such that a width of the recess 316 decreases from an upper portion to a lower portion of the recess 316. An angle a formed between the tapered side walls and a horizontal plane (e.g., parallel with a bottom surface of the first piezoelectric layer 314) is between 20 and 55 degrees. In one embodiment, the recess 316 extends from the top surface of the first piezoelectric layer 314 towards the bottom surface of the first piezoelectric layer 314 without completely extending through the first piezoelectric layer 314. A thin piezoelectric section 314-F of the first piezoelectric layer 314 is directly underneath the recess 316. In one embodiment, the recess 316 may extend completely through the first piezoelectric layer 314 from the top surface of the first piezoelectric layer 314 to the bottom surface of the first piezoelectric layer 314 (not shown). The recess 316 is vertically above the second reflector 330-2.

The second piezoelectric layer 318 fully fills the recess 316, such that the second piezoelectric layer 318 is also vertically above the second reflector 330-2. In one embodiment, a top surface of the second piezoelectric layer 318 and a top surface of the first piezoelectric layer 314 are coplanar. The first piezoelectric layer 314 and the second piezoelectric layer 318 are formed of two different piezoelectric materials, each of which is one of lithium tantalate (LT), lithium niobate, quartz, AlN, ScAlN, MgHfAlN, MgZrAlN, and MgTiAlN. In a non-limited example, the first piezoelectric layer 314 may be formed of LT, while the second piezoelectric layer 118 may be formed of AlN or ScAlN. In addition, the first piezoelectric layer 314 has a thickness between 0.3 μm and 1.4 μm, and the second piezoelectric layer 318 has a thickness between 0.2 μm and 1 μm. When the recess 316 does not extend completely through the first piezoelectric layer 314, the thin piezoelectric section 314-F has a thickness the thin piezoelectric section 114-F has a thin thickness between 0 μm and 0.2 μm, or between 20 nm and 40 nm, and is vertically located between the second piezoelectric layer 318 and the second reflector 330-2. When the recess 316 extends completely through the first piezoelectric layer 314, the thin piezoelectric section 314-F is omitted, and the second piezoelectric layer 318 is in contact with the second reflector 330-2 (not shown).

Notice that, in some applications, such as the common SAW resonator applications or the TC SAW resonator applications, the reflection structure 310 is omitted in the alternative acoustic wave device 300. As such, the first piezoelectric layer 314 is in contact with the substrate 306. If the recess 316 extends completely through the first piezoelectric layer 314, the second piezoelectric layer 318 is also in contact with the substrate 306.

The first IDT electrodes 320 are formed over the first piezoelectric layer 314, while the second IDT electrodes 322 are formed over and confined within the second piezoelectric layer 318. Each IDT electrode 320/322 may be formed of aluminum or the like.

The first SAW resonator 302 is composed of the first reflector 330-1, the first IDT electrodes 320, and a portion of the first piezoelectric layer 314 vertically below the first IDT electrodes 320. The second SAW resonator 304 is composed of the second reflector 330-2, the second IDT electrode 322, and the second piezoelectric layer 318. When the recess 316 does not extend completely through the first piezoelectric layer 314, the second SAW resonator 304 further includes the thin piezoelectric section 314-F. Due to the relatively thin thickness of the thin piezoelectric section 314-F (compared to the thickness of the second piezoelectric layer 318), the second resonator 304 is essentially based on the quality factor and the electromechanical coupling coefficient of the second piezoelectric layer 318.

Notice that, if the first and second SAW resonators 302 and 304 are common SAW resonators or TC SAW resonators, the first resonator 302 does not include the first reflector 330-1 and is composed of the first IDT electrodes 320 and the portion of the first piezoelectric layer 314 vertically below the first IDT electrodes 320. The second resonator 304 does not include the second reflector 330-2 and is composed of the second IDT electrodes 322 and the second piezoelectric layer 118 vertically below the second IDT electrodes 322. Regardless of the presence or absence of the reflectors 330, the alternative acoustic wave device 300 with the first SAW resonator 302 and the second SAW resonator 304 is formed on one acoustic wave wafer by a same manufacturing process.

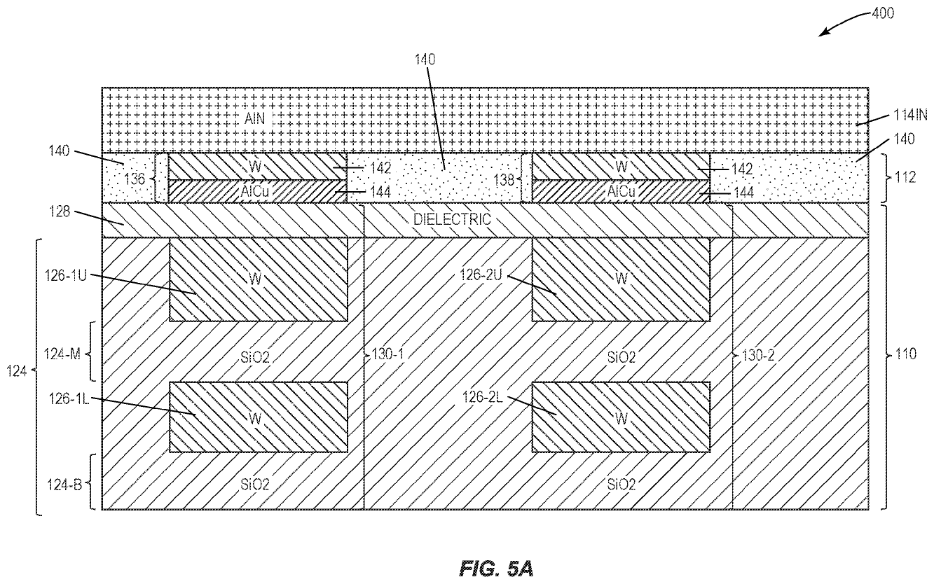

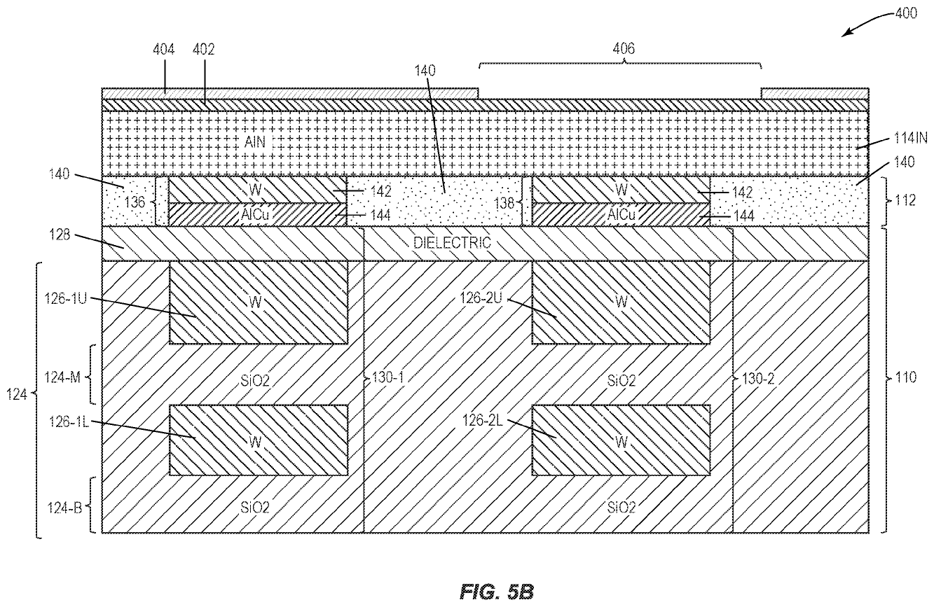

FIGS. 5A-11 provide an exemplary manufacturing process to implement the acoustic wave device 100 shown in FIG. 1. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 5A-11.

Initially, an acoustic wave device precursor 400 is provided as illustrated in FIGS. 5A and 5B. In FIG. 5A, the acoustic wave device precursor 400 includes the reflection structure 110, the bottom electrode structure 112 over the reflection structure 110 and an intact first piezoelectric layer 114IN over the bottom electrode structure 112. The intact first piezoelectric layer 114IN may be formed of AlN with a thickness between 0.3 μm and 1.4 μm. The intact first piezoelectric layer 114IN has a flat surface without any recess. For some applications, the acoustic wave device precursor 400 may further include a mask layer 402 formed over the intact first piezoelectric layer 114IN and a resist pattern 404 with an opening 406 formed over the mask layer 402, as illustrated in FIG. 5B. Herein, the mask layer 402 may be formed of W and the resist pattern 404 may be formed of a photoresist material. The opening 406 is vertically above the second bottom electrode 138 of the bottom electrode structure 112 and may have a width wider than the second bottom electrode 138. In some applications, such as FBAR applications, the reflection structure 110 is omitted in the acoustic wave device precursor 400.

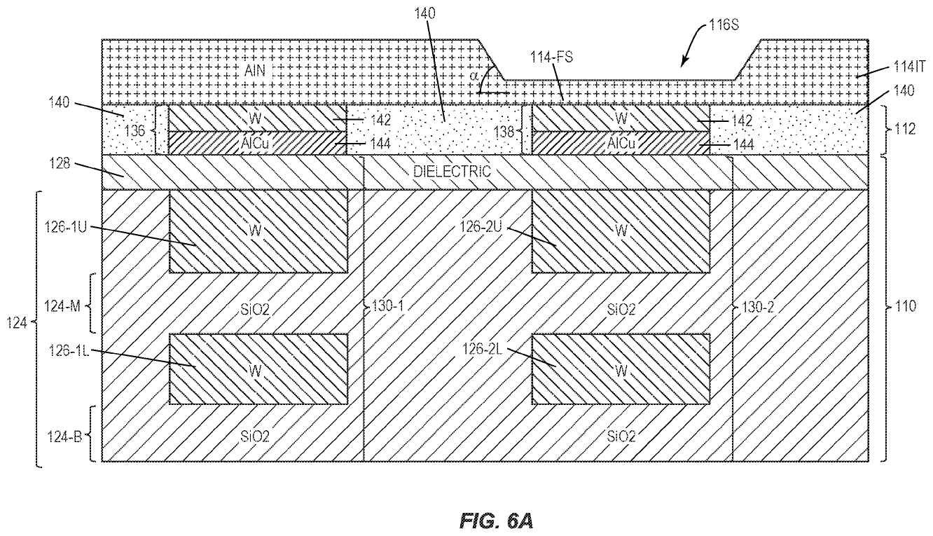

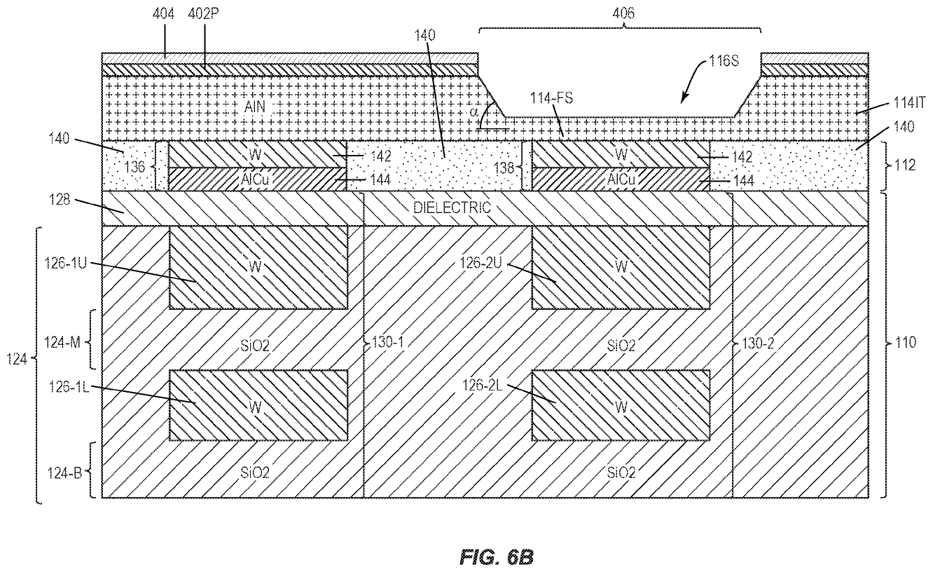

Next, a starting recess 116S is formed extending from a top surface of the intact first piezoelectric layer 114IN towards a bottom surface of the intact first piezoelectric layer 114IN to provide an intermediate first piezoelectric layer 114IT, as illustrated in FIG. 6A. The starting recess 116S has tapered sidewalls such that a width of the starting recess 116S decreases from an upper portion to a lower portion of the starting recess 116S. An angle a formed between the tapered side walls of the starting recess 116S and a horizontal plane (e.g., parallel with a bottom surface of the intermediate first piezoelectric layer 114IT) is between 20 and 55 degrees. Herein, the starting recess 116S does not extend completely through the intermediate first piezoelectric layer 114IT. A piezoelectric section 114-FS remains directly underneath the starting recess 116S. In one embodiment, the starting recess 116S may be formed by a piezoelectric milling process, which can be precisely controlled to form the tapered sidewalls. In another embodiment, the starting recess 116S may be formed by a dry-etching process. Due to the non-uniformity of the piezoelectric milling process or the non-uniformity of the dry-etching process, the remaining piezoelectric section 114-FS may need a thickness of at least 75 nm (e.g., between 75 nm and 0.25 μm).

Alternatively, if the acoustic wave device precursor 400 includes the mask layer 402 and the resist pattern 404 with the opening 406, besides forming the starting recess 116S, a portion of the mask layer 402 is also removed to provide a mask pattern 402P, as illustrated in FIG. 6B. The mask pattern 402P has an opening with a same size as the opening 406 of the resist pattern 404. The top portion (e.g., the widest portion) of the starting recess 116S also has a same size as the opening 406 of the resist pattern 404. Herein, the mask pattern 402P and the starting recess 116S may be formed by a same wet-etching process. Due to the non-uniformity of the wet-etching process, the remaining piezoelectric section 114-FS needs a thickness of at least 75 nm (e.g., between 75 nm and 0.25 μm).

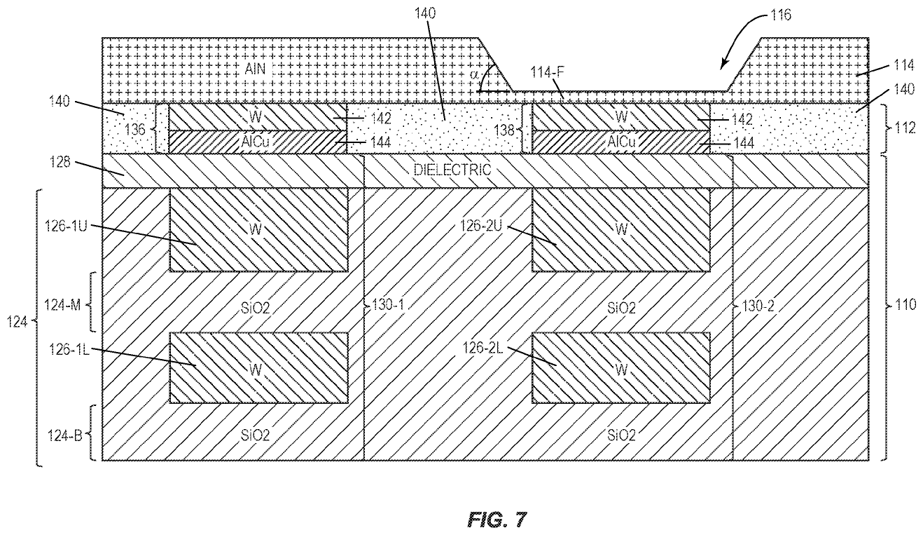

FIG. 7 shows a flattening trim step to provide the recess 116 within the first piezoelectric layer 114. The remaining piezoelectric section 114-FS is thinned down to the thin piezoelectric section 114-F, which has a thickness between 0 μm and 0.2 μm, or between 20 nm and 40 nm. The thin piezoelectric section 114-F acts as a seed layer for piezoelectric layer deposition. As such, the thin piezoelectric section 114-F has a high uniformity requirement, which has a direct impact on an electromechanical coupling coefficient of the deposited piezoelectric material (details described below). Herein, the high uniformity requirement indicates that a top surface of the thin piezoelectric section 114-F has a roughness less than 1 nm. The recess 116 keeps the tapered sidewalls as the starting recess 116S with the same angle a between 20 and 55 degrees. The remaining piezoelectric section 114-FS is thinned down to the thin piezoelectric section 114-F by a trimming process. In addition, if the mask pattern 402P and the resist pattern 404 are over the intermediate first piezoelectric layer 114IT (as shown in FIG. 6B), the mask pattern 402P and the resist pattern 404 may be removed before or after the flattening trim step (not shown).

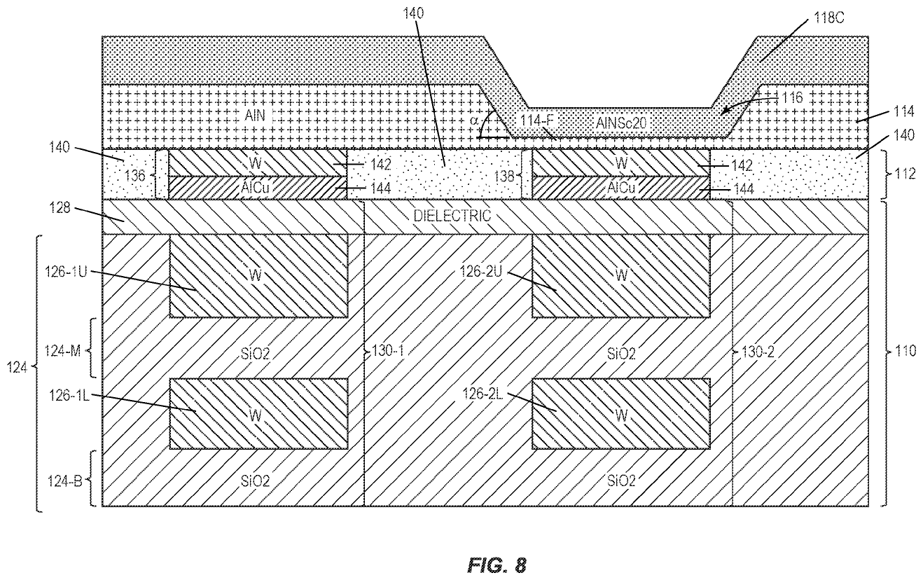

After the recess 116 within the first piezoelectric layer 114 is formed, a common second piezoelectric layer 118C is deposited covering the entire first piezoelectric layer 114, as illustrated in FIG. 8. The common second piezoelectric layer 118C is in contact with the entire top surface of the first piezoelectric layer 114 and exposed surfaces within the recess 116. Because of the relatively small angle a, the deposition of the common second piezoelectric layer 118C will face less risk of cracking. The thin piezoelectric section 114-F is a seed layer for the deposition of the common second piezoelectric layer 118C within the recess 116. The uniformity of the thin piezoelectric section 114-F will affect the electromechanical coupling coefficient of the common second piezoelectric layer 118C (especially, the electromechanical coupling coefficient of a portion of the common second piezoelectric layer 118C vertically located above the thin piezoelectric section 114-F). The common second piezoelectric layer 118C may be formed of ScAlN, MgHfAlN, MgZrAlN, or MgTiAlN with a thickness between 0.2 μm and 1 μm.

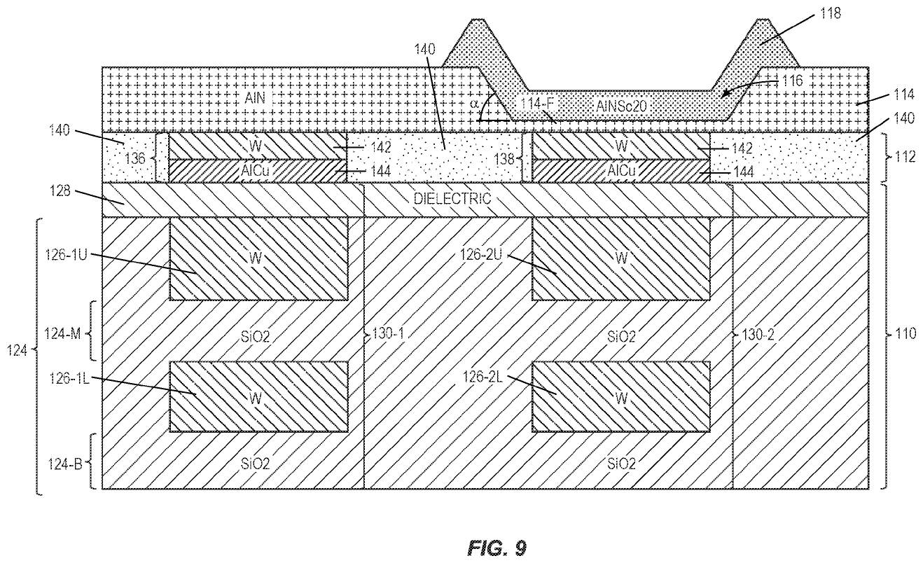

The common second piezoelectric layer 118C is then patterned to provide the second piezoelectric layer 118, as illustrated in FIG. 9. The second piezoelectric layer 118 fully covers the recess 116 and extends over the top surface of the first piezoelectric layer 114 without covering the portion of the first piezoelectric layer 114 vertically located above the first bottom electrode 136. As such, the second piezoelectric layer 118 is vertically located above the second bottom electrode 138 within the bottom electrode structure 112. The common second piezoelectric layer 118C is patterned by a piezoelectric milling process or an etching process.

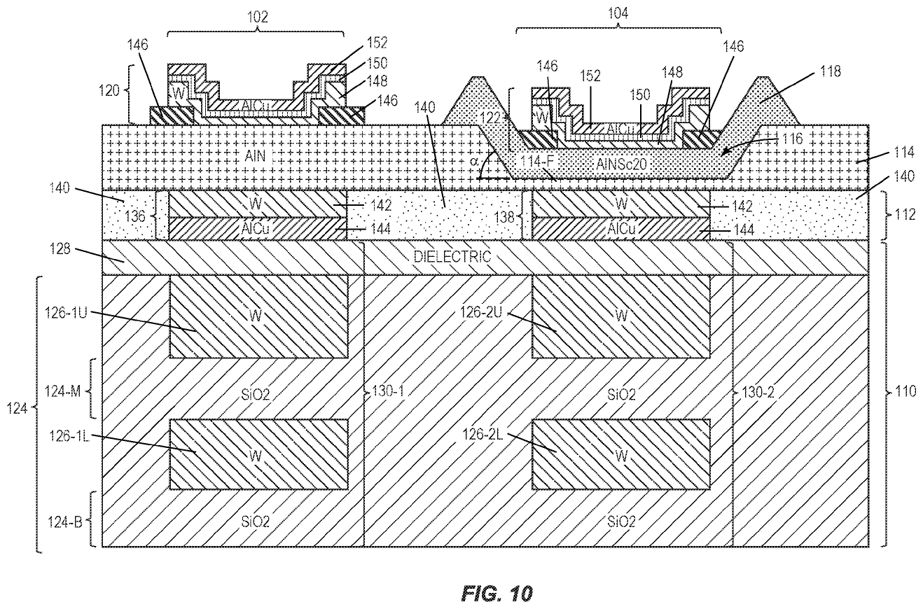

Next, the first top electrode 120 is formed over the first piezoelectric layer 114 and vertically above the first bottom electrode 136 to complete the first resonator 102, and the second top electrode 122 is formed over the second piezoelectric layer 118, confined within the recess 116, and vertically above the second bottom electrode 138 to complete the second resonator 104, as illustrated in FIG. 10. Lastly, the passivation layer 160 is formed to complete the acoustic wave device 100. The passivation layer 160 covers the first top electrode 120, the second top electrode 122, portions of the first piezoelectric layer 114 exposed through the first top electrode 120 and the second piezoelectric layer 118, and portions of the second piezoelectric layer 118 exposed through the second top electrode 122.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. An acoustic wave device, comprising:
at least one first electrode;
at least one second electrode;
a first piezoelectric layer with a first recess that extends from a top surface of the first piezoelectric layer towards a bottom surface of the first piezoelectric layer; and
a second piezoelectric layer fully covering the first recess, wherein:
the at least one first electrode is formed over the first piezoelectric layer, and the at least one second electrode is formed over the second piezoelectric layer and horizontally confined within the first recess, wherein no portion of the first piezoelectric layer exists vertically between the second piezoelectric layer and the at least one second electrode;
the second piezoelectric layer does not cover a portion of the first piezoelectric layer, which is vertically underneath the at least one first electrode; and
the first piezoelectric layer and the second piezoelectric layer are formed of different piezoelectric materials.

2. The acoustic wave device of claim 1 wherein the first recess has tapered sidewalls, such that a width of the first recess decreases from an upper portion to a lower portion of the first recess, wherein an angle formed between the tapered side walls and a horizontal plane is between 20 and 55 degrees.

3. The acoustic wave device of claim 1 wherein:
the first recess does not extend completely through the first piezoelectric layer;
the first piezoelectric layer includes a first piezoelectric section directly underneath the first recess, such that the second piezoelectric layer is formed over first piezoelectric section; and
the first piezoelectric section has a thickness between 0 μm and 0.2 μm.

4. The acoustic wave device of claim 1 wherein the first piezoelectric layer and the second piezoelectric layer have different quality factors and different electromechanical coupling coefficients.

5. The acoustic wave device of claim 4 each of the first piezoelectric layer and the second piezoelectric layer is formed of one of a group consisting of aluminum nitride (AlN), scandium-doped aluminum nitride (ScAlN), magnesium hydrofluoric acid aluminum nitride (MgHfAlN), magnesium zirconium aluminum nitride (MgZrAlN), and magnesium titanium aluminum nitride (MgTiAlN).

6. The acoustic wave device of claim 5 wherein:
the first piezoelectric layer is formed of AlN; and
the second piezoelectric layer is formed of one of a group consisting of ScAlN, MgHfAlN, MgZrAlN, and MgTiAlN.

7. The acoustic wave device of claim 5 further comprising a bottom electrode structure with a first bottom electrode and a second bottom electrode, wherein:
the at least one first electrode includes a first top electrode, and the at least one second electrode includes a second top electrode;
the second piezoelectric layer extends over a top surface of the first piezoelectric layer;
the bottom electrode structure is formed underneath the first piezoelectric layer;
the first bottom electrode is vertically underneath the first top electrode, and the second bottom electrode is vertically underneath the second top electrode;
a first resonator is composed of at least the first bottom electrode, the first top electrode, and a portion of the first piezoelectric layer vertically between the first bottom electrode and the first top electrode; and
a second resonator is composed of at least the second bottom electrode, the second top electrode, and the second piezoelectric layer.

8. The acoustic wave device of claim 7 further includes a reflection structure with a first reflector and a second reflector, wherein:
each of the first reflector and the second reflector has alternating high acoustic impedance sections and low acoustic impedance sections;
the first reflector is vertically underneath the first bottom electrode, and the first resonator further includes the first reflector; and
the second reflector is vertically underneath the second bottom electrode, and the second resonator further includes the second reflector.

9. The acoustic wave device of claim 4 wherein:
the first piezoelectric layer is formed of lithium tantalate (LT), Lithium niobate, or quartz; and
the second piezoelectric layer is formed of one of a group consisting of AlN, ScAlN, MgHfAlN, MgZrAlN, and MgTiAlN.

10. The acoustic wave device of claim 9 wherein:
the at least one first electrode includes two or more first interdigital transducer (IDT) electrodes, and the at least one second electrode includes two or more second IDT electrodes;
the first IDT electrodes are formed over the first piezoelectric layer, and the second IDT electrodes are formed over the second piezoelectric layer and are confined within the second piezoelectric layer;
a first resonator is composed of at least the first IDT electrodes and a portion of the first piezoelectric layer vertically underneath the first IDT electrodes; and
a second resonator is composed of at least the second IDT electrodes and the second piezoelectric layer underneath the second IDT electrodes.

11. The acoustic wave device of claim 10 wherein a top surface of the first piezoelectric layer and a top surface of the second piezoelectric layer are coplanar.

12. The acoustic wave device of claim 1 wherein:
the at least one first electrode includes multiple first top electrodes, and the at least one second electrode includes multiple second top electrodes;
the first piezoelectric layer further includes a second recess;
the second piezoelectric layer continuously covers both the first recess and the second recess, and does not cover any portion of the first piezoelectric layer, which is vertically underneath each of the multiple first top electrodes; and
the multiple first top electrodes are formed over the first piezoelectric layer, and the multiple second top electrodes are formed over the second piezoelectric layer, wherein two of the multiple second top electrodes are confined within the first recess and the second recess, respectively.

13. A method comprising:
providing an acoustic wave device precursor including an intact first piezoelectric layer;
forming a first piezoelectric layer with a recess by removing a portion of the intact first piezoelectric layer, wherein the recess extends from a top surface of the intact first piezoelectric layer towards a bottom surface of the intact first piezoelectric layer;
depositing a common second piezoelectric layer covering the entire first piezoelectric layer, such that the common second piezoelectric layer is in contact with an entire top surface of the first piezoelectric layer and exposed surfaces within the recess;
patterning the common second piezoelectric layer to provide a second piezoelectric layer, wherein:
the second piezoelectric layer fully covers the recess and does not cover the entire first piezoelectric layer; and
the first piezoelectric layer and the second piezoelectric layer are formed of different piezoelectric materials; and
forming at least one first electrode over the first piezoelectric layer, and at least one second electrode over the second piezoelectric layer and horizontally confined within the recess, wherein the at least one first electrode does not have overlap with the second piezoelectric layer, and no portion of the first piezoelectric layer exists vertically between the second piezoelectric layer and the at least one second electrode.

14. The method of claim 13 wherein forming the recess comprises:
forming a starting recess from the top surface of the intact first piezoelectric layer towards the bottom surface of the intact first piezoelectric layer without completely extending through the intact first piezoelectric layer, wherein a piezoelectric section of the intact first piezoelectric layer remains directly underneath the starting recess; and
thinning down the remaining piezoelectric section to provide the recess with a thinned piezoelectric section directly underneath the recess.

15. The method of claim 14 wherein:
the starting recess is formed by one of a piezoelectric milling process, a dry-etching process, and a wet-etching process;
the remaining piezoelectric section is thinned down by a trimming process;
a top surface of the thinned piezoelectric section has a roughness less than 1 nm; and
the thinned piezoelectric section has a thickness between 0 and 0.2 μm.

16. The method of claim 13 wherein the recess has tapered sidewalls, such that a width of the recess decreases from an upper portion to a lower portion of the recess, wherein an angle formed between the tapered side walls and a horizontal plane is between 20 and 55 degrees.

17. The method of claim 13 wherein the common second piezoelectric layer is patterned by one of a piezoelectric milling process, a dry-etching process, and a wet-etching process.

18. The method of claim 13 wherein the first piezoelectric layer and the second piezoelectric layer have different quality factors and different electromechanical coupling coefficients.

19. The method of claim 18 wherein each of the first piezoelectric layer and the second piezoelectric layer is formed of one of a group consisting of AlN, ScAlN, MgHfAlN, MgZrAlN, and MgTiAlN.

20. The method of claim 19 wherein:
the first piezoelectric layer is formed of AlN; and
the second piezoelectric layer is formed of one of a group consisting of ScAlN, MgHfAlN, MgZrAlN, and MgTiAlN.
